(19) United States
(12) Patent Application Publication
(10) Pub. No.: US 2009/0152643 A1
(43) Pub. Date: Jun. 18, 2009

(54) Semiconductor structures

(76) Inventors: Mine-Yuan Huang, Taipei City (TW); Li-Hung Chi, Taipei County (TW)

Correspondence Address: Muncy, Geissler, Olds & Lowe, PLLC, P.O. BOX 1364, FAIRFAX, VA, 22038-1364, US

(21) Appl. No.: 12/073,762

(22) Filed: Mar. 10, 2008

(30) Foreign Application Priority Data
Dec. 18, 2007 (TW) 096221525

(51) Int. Cl. H01L 27/06

(52) U.S. Cl. 257/370; 257/E27.015

(57) ABSTRACT

A semiconductor structure is provided. The semiconductor structure comprises a substrate, a first metal-oxide-semiconductor (MOS), a second MOS, a first semiconductor region, and a second semiconductor region. The first and the second MOSs are formed on the substrate. The first semiconductor region is formed between the substrate and the first MOS. The second semiconductor region is formed between the substrate and the second MOS. The first semiconductor region and the second semiconductor region isolate the first MOS from the second MOS.

### BACKGROUND OF THE INVENTION

1. Field of the Invention

The invention relates to a semiconductor structure, and more particularly to a semiconductor structure preventing latch-up condition.

2. Description of the Related Art

The most important basic electronic components in semiconductor technique are metal-oxide-semiconductors (MOS) transistors, which comprise the N-type MOS (NMOS) structure, the P-type MOS (PMOS) structure, and the complementary MOS (CMOS) structure. A complete integrated circuit usually comprises thousands and thousands of MOS structures. As semiconductors become denser, distances between NMOS structures and PMOS structures become more significant of an issue. If distances between NMOS structures and PMOS structures are too small or unsuitable, parasitical elements of CMOS structures, such as PNP transistors, NPN transistors, or diodes, may be triggered to an operating state, affecting normal operation of the CMOS circuits. In some conditions, the CMOS structures can not work normally, and chips where the CMOS structures are disposed lose efficacy due to insufficient voltage. In some conditions, even if sufficient voltage is provided, the chips continuously receive large currents, resulting in damage to the chips, thus putting the chips in a latch-up condition.

FIG. 1 shows a conventional semiconductor structure. Referring to FIG. 1, in a semiconductor structure 10, when input current is generated from positive trigger current of a pad PAD, the input current flows through a transistor Q_{PNP} and from a well D_{NWELL} to a well P_{WELL} to turn on the transistor Q_{PNP}. When voltage drop generated by a resistor R_{PWELL} is sufficient to direct the base voltage of a transistor Q_{NPN} to be larger than an emitter voltage thereof by 0.7 volts, the transistor Q_{NPN} is turned on, and positive feedback is generated to turn on a semiconductor controlled rectifier (PNPN). That is, a region P_{S} is at a positive potential, the well D_{NWELL}, the well P_{WELL}, and a region N_{S} are at a negative potential, thus, creating a latch-up condition. Similarly, negative trigger current of the pad PAD flows from and through the transistor Q_{PNP} and from the well P_{WELL} to a well D_{NWELL}, to turn on the transistor Q_{NPN}. When voltage drop generated by a resistor R_{NWELL} is sufficient to direct the base voltage of the transistor Q_{PNP} to be less than an emitter voltage thereof by 0.7 volts, the transistor Q_{PNP} is turned on, and positive feedback is generated to turn on the semiconductor controlled rectifier (PNPN). That is, the region P_{S} is at a positive potential, the well D_{NWELL}, the well P_{WELL}, and a region N_{S} are at a negative potential, thus, creating a latch-up condition. According to above description, both of these two cases generate positive feedback, and the latch-up condition further occurs, resulting in serious circuitry problems.

Thus, it is desired to provide a new semiconductor structure to solve the problems due to the latch-up condition in conventional semiconductor structures.

### BRIEF SUMMARY OF THE INVENTION

An exemplary embodiment of a semiconductor structure comprises a substrate, a first metal-oxide-semiconductor (MOS), a second MOS, a first semiconductor region, and a second semiconductor region. The first and the second MOSs are formed on the substrate. The first semiconductor region is formed between the substrate and the first MOS. The second semiconductor region is formed between the substrate and the second MOS. The first semiconductor region and the second semiconductor region isolate the first MOS from the second MOS, thereby preventing a latch-up condition.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a conventional semiconductor structure; and

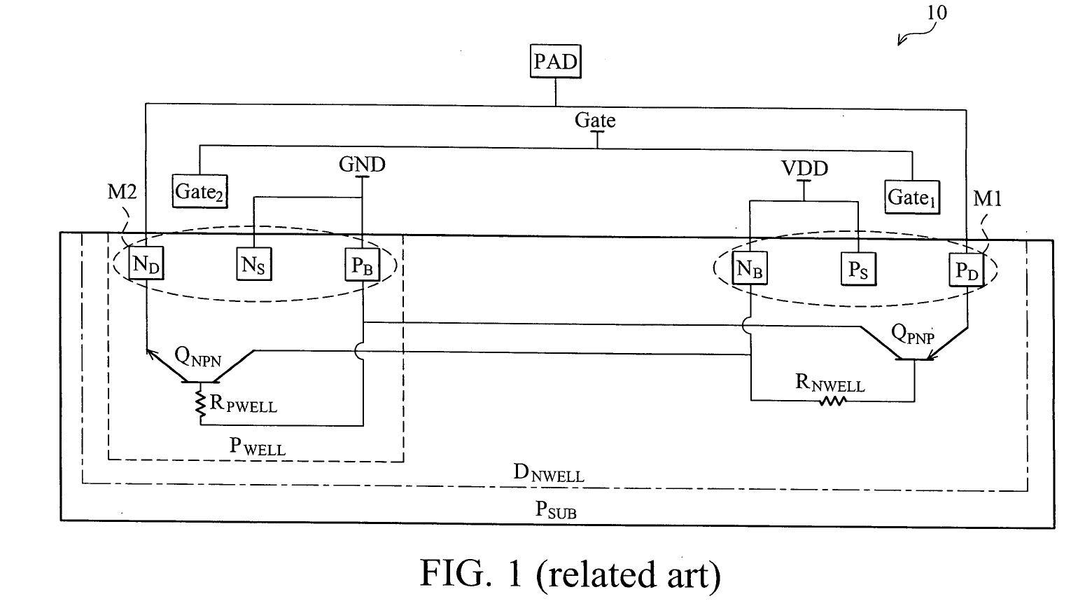

FIG. 2 is an exemplary embodiment of a semiconductor structure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

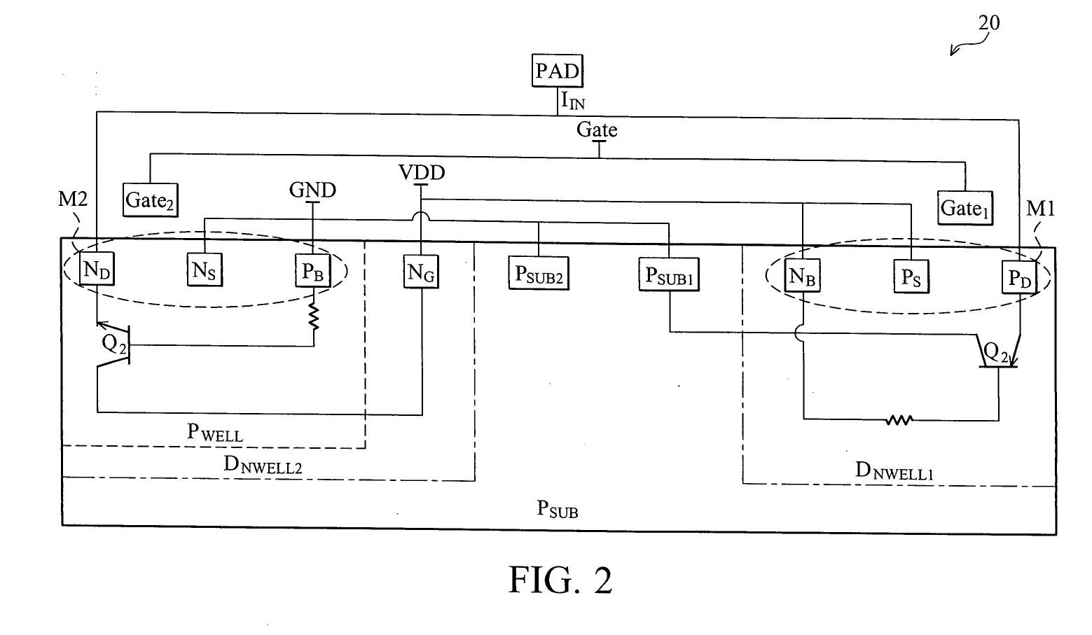

Semiconductor structures are provided. In an exemplary embodiment of a semiconductor structure as shown in FIG. 2, a semiconductor structure 20 comprises a substrate P_{SUB}, a first metal-oxide-semiconductor (MOS) M1, a second MOS M2, a first semiconductor region D_{NWELL1}, and a second semiconductor region D_{NWELL2}. In one embodiment, the substrate P_{SUB} is a P-type substrate. The first MOS M1 is formed on the substrate P_{SUB}. The second MOS Ma is formed on the substrate P_{SUB}. The first semiconductor region D_{NWELL1} is formed between the substrate P_{SUB} and the first MOS M1. The second semiconductor region D_{NWELL2} is formed between the substrate P_{SUB} and the second MOS M2. The first semiconductor region D_{NWELL1} and the second semiconductor region D_{NWELL2} are used to isolate the first MOS M1 from the second MOS M2. In this embodiment, the first MOS M1 is a P-type MOS, while the second MOS M2 is an N-type MOS. Each of the first semiconductor region D_{NWELL1} and the second semiconductor region D_{NWELL2} is formed by a deep N-well.

Referring to FIG. 2, the semiconductor structure 20 further comprises a third semiconductor region P_{WELL}. In one embodiment, the third semiconductor region P_{WELL} is formed by a p-well. The third semiconductor region P_{WELL} is formed between the second MOS M2 and the second semiconductor region D_{NWELL2}.

In one embodiment, the first MOS M1 comprises a P-type drain P_{D}, a P-type source P_{S}, and an N-type base N_{B}, wherein the P-type source P_{S} and the N-type base N_{B} are coupled to a first voltage source VDD. Referring to FIG. 2, the semiconductor structure 20 further comprises a first P-type planting region P_{SUB1}. The first P-type planting region P_{SUB1} is coupled to the P-type drain P_{D}, the N-type base N_{B}, and a second voltage source GND to form a first transistor Q1, wherein the second voltage source GND is a ground terminal. In one embodiment, the first transistor Q1 is a parasitical PNP bipolar transistor. In this embodiment, the first transistor Q1 is a vertical PNP bipolar transistor.

The second MOS M2 comprises an N-type drain N_{D}, an N-type source N_{S}, and a P-type base P_{B}, wherein the N-type source N_{S} and the P-type base P_{B} are coupled to the second voltage source GND. The N-type drain N_{D}, the N-type source N_{S}, and the P-type base N_{P} are formed in the third semiconductor structure P_{WELL}. Referring to FIG. 2, the semiconductor structure 20 further comprises a deep N-type well N_{G}. The deep N-type well N_{G} is coupled to the N-type drain N_{D}, the P-type base P_{B}, and the first voltage source VDD to form a second transistor Q2. In one embodiment, the second transistor Q2 is a parasitical NPN bipolar transistor. In this embodiment, the second transistor Q2 is a vertical NPN bipolar transistor. In one embodiment, the semiconductor structure 20 further comprises a second P-type planting region P_{SUB2}, which is coupled to the second voltage source GND. In another embodiment, the semiconductor structure 20 further comprises a first gate planting region Gate₁ and a second gate planting region Gate₂. The first gate planting region Gate₁ is coupled between the P-type drain P_{D} and the P-type source P_{S}, while the second gate planting region Gate₂ is coupled between the N-type drain N_{D} and the N-type source N_{S}.

The semiconductor structure 20 further comprises a pad PAD, which is coupled to the P-type drain P_{D} and the N-type drain N_{D}, for inputting input current I_{IN}.

According to the semiconductor structure 20, the deep N-well D_{NWELL2} is used to isolate the P-type MOS M1 and the N-type MOS M2, and the second P-type planting region P_{SUB2} coupled to the ground is formed between the P-type MOS M1 and the N-type MOS M2. Thus, positive trigger current from the pad PAD flows from the first transistor Q₁ (PNP bipolar transistor) to the ground terminal GND. Moreover, since the first P-type planting region P_{SUB1} is isolated from the second P-type planting region P_{SUB2}, the second P-type planting region P_{SUB2} can remain at a low voltage level of the ground terminal GND. The deep N-type well D_{NWELL2} is coupled to the first voltage source VDD. Thus, forward turned-on state can not occur between the P-type substrate P_{SUB} and the deep N-type well D_{NWELL2}, so that P_{S}NPN_{S} (P_{S} representing a positive potential, N representing an N-type well, P representing a P-type substrate, and N_{S} representing a negative potential) path of a conventional semiconductor controlled rectifier is not generated, preventing a latch-up condition.

Additionally, negative trigger current from the pad PAD flows from the second transistor Q₂ (NPN bipolar transistor) to the ground terminal GND. Moreover, since the first P-type planting region P_{SUB1} is isolated from the second P-type planting region P_{SUB2}, the second P-type planting region P_{SUB2} can remain at a low voltage level of the ground terminal GND. The P-type well P_{WELL} is coupled to the ground terminal GND. Thus, an inverse base is generated between the P-type substrate P_{SUB} and the deep N-type well D_{NWELL2}, so that P_{S}NPN_{S} path of a conventional semiconductor controlled rectifier is not generated, preventing a latch-up condition.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure comprising:
a substrate;
a first metal-oxide-semiconductor (MOS) formed on the substrate;
a second MOS formed on the substrate;
a first semiconductor region formed between the substrate and the first MOS; and
a second semiconductor region formed between the substrate and the second MOS,
wherein the first semiconductor region and the second semiconductor region isolate the first MOS from the second MOS.

2. The semiconductor structure as claimed in claim 1, wherein the substrate is a P-type substrate.

3. The semiconductor structure as claimed in claim 2 further comprising a third semiconductor region formed between the second MOS and the second semiconductor region.

4. The semiconductor structure as claimed in claim 3, wherein each of the first and the second semiconductor regions is formed by a deep N-type well.

5. The semiconductor structure as claimed in claim 4, wherein the third semiconductor region is formed by a P-type well.

6. The semiconductor structure as claimed in claim 5, wherein the first MOS is a P-type MOS (PMOS).

7. The semiconductor structure as claimed in claim 6, wherein the first MOS comprises a P-type drain, a P-type source, and an N-type base, and the P-type source and the N-type base are coupled to a first voltage source.

8. The semiconductor structure as claimed in claim 7 further comprising a first P-type planting region, wherein the P-type planting region is coupled to the P-type drain, the N-type base, and a second voltage source to form a first transistor.

9. The semiconductor structure as claimed in claim 8, wherein the first transistor is a parasitical PNP bipolar transistor.

10. The semiconductor structure as claimed in claim 8, wherein the first transistor is a vertical PNP bipolar transistor.

11. The semiconductor structure as claimed in claim 10, wherein the second MOS is an N-type MOS (NMOS).

12. The semiconductor structure as claimed in claim 11, wherein the second MOS comprises an N-type drain, an N-type source, and a P-type base, and the N-type source and the P-type base are coupled to the second voltage source.

13. The semiconductor structure as claimed in claim 12 further comprising a second P-type planting region coupled to the second voltage source.

14. The semiconductor structure as claimed in claim 13, wherein the second source voltage is a ground terminal.

15. The semiconductor structure as claimed in claim 14, wherein the N-type drain, the N-type source, and the P-type base are formed in the third semiconductor region.

16. The semiconductor structure as claimed in claim 15 further comprising a deep N-type well, the deep N-type well is coupled to the N-type drain, the P-type base, and the first voltage source to form a second transistor.

17. The semiconductor structure as claimed in claim 16, wherein the second transistor is a parasitical NPN bipolar transistor.

18. The semiconductor structure as claimed in claim 16, wherein the second transistor is a vertical NPN bipolar transistor.

19. The semiconductor structure as claimed in claim 18 further comprising a first gate planting region and a second gate planting region, wherein the first gate planting region is coupled between the P-type drain and the P-type source, and the second gate planting region is coupled between the N-type drain and the N-type source.

20. The semiconductor structure as claimed in claim 19 further comprising a pad coupled to the P-type drain and the N-type drain for inputting input current.
